(19) United States
(12) Patent Application Publication
(10) Pub. No.: US 2022/0050374 A1
(43) Pub. Date: Feb. 17, 2022

(54) PROTECTIVE FILM WITH HIGH HARDNESS AND LOW FRICTION COEFFICIENT

(71) Applicant: Feedback Technology Corp., Hsinchu City (TW)

(72) Inventors: Tsung Feng Wu, Hsinchu City (TW); Yu Yen Tsai, Hsinchu City (TW); Wen-Lian Lee, Hsinchu City (TW); Hui Huan Yu, Hsinchu City (TW); Kuan Ting Chou, Hsinchu City (TW)

(73) Assignee: Feedback Technology Corp., Hsinchu City (TW)

(21) Appl. No.: 17/105,540

(22) Filed: Nov. 26, 2020

(30) Foreign Application Priority Data
Aug. 17, 2020 (TW) 109127982

(51) Int. Cl. G03F 1/48; G03F 1/66

(52) U.S. Cl. CPC G03F 1/48; G03F 1/66

(57) ABSTRACT

A protective film with high hardness and low friction coefficient includes an interface layer, a buffer layer, and a high-hardness passivation layer. The protective film has good wear resistance and low friction coefficient and can be applied to a mask package box for photolithography such as a deep ultraviolet (DUV) lithography, an extreme ultraviolet (EUV) lithography, an immersion lithography and a multiple patterning lithography of the photovoltaic and semiconductor industries. The protective film is used to protect the mask package box applied for photolithographic exposure and ensure the yield of the photolithographic process.

### BACKGROUND OF THE INVENTION

### Field of the Invention

The present invention relates to a photovoltaic and semiconductor process that requires a high level of cleanliness for manufacture in the industries such as IC, LCD panel, LED, MEMS, solar panel, and electronic paper, particularly in the technical field of photolithography manufacturing processes. More particularly, this invention relates to a protective film with high hardness and low friction coefficient of a mask package box applied in a photolithography of the photovoltaic and semiconductor industries to improve the yield of the photolithography.

### Description of Related Art

In the lithography of the photovoltaic and semiconductor industries, a mask is used to project light onto a photoresist for exposure and development, and the area irradiated by the light produces a chemical reaction and changes a bonding, and the photoresist at the area irradiated by light can be removed or retained to achieve the effect of circuit patterning, and then an etching process is used to reduce the circuit into a very small pattern.

To lower costs, major semiconductor OEM manufacturers and photoelectric companies are committed to increase the density of components which depends on the pitch (also known as line width) between a drain and a source of a metal oxide semiconductor field effect transistor (MOSFET). The density of components can be increased by slightly reducing the line width. However, a slight reduction of the line width means that the line width of a pattern on a mask must be reduced slightly, so that the cleanliness of the body of the mask becomes more and more important. Any contaminant on the mask will cause errors to the pattern transfer or even cause a poor removal of the photoresist, so as to affect the subsequent processes and lead to rework or even scrap of wafers.

To improve the yield of the photolithography, a metal film barrier layer is generally coated onto the surface of a mask package box 100 in a prior art (Please refer to FIG. 1 for the exploded view of a conventional mask package box 100) to keep the cleanliness from airborne dust pollution. However, the metal film barrier layer can no longer meet the dust resistance requirement due to the gradually decreasing line width and the gradually shortening pitch between lines. Any production of particles may cause errors to the exposure. The conventional mask package box is made of metal, and thus the performance on hardness and wear resistance is lower, and metals react with air easily to form a native oxide layer, and such oxide layer has a loosened structure and may fall off easily by external forces or collisions, and the mask may be contaminated easily by particles.

Obviously, it is a main subject for related manufacturers to design a protective film with high hardness and low friction coefficient by a higher specification for the mask package box. In fact, if the wear resistance of the substrate surface can be improved and the friction coefficient of the substrate surface can be reduced, then the production and adhesion of dust will be reduced. In addition, the protective films of this sort generally have a higher sheet resistance, and the thickness and structure can be adjusted to control the resistance within a static dissipative range, so as to further reduce the adhesion of the dust.

In view of the drawbacks of the prior art, the inventor of the present invention based on years of experience in the related industry to conduct extensive research and experiment, and finally designed and developed a protective film with high hardness and low friction coefficient for the mask package box to ensure the yield of the photolithography.

### SUMMARY OF THE INVENTION

It is a primary objective of the present invention to provide a protective film with high hardness and low friction coefficient applied onto a mask package box used for any photolithography in the photovoltaic and semiconductor industries, and the protective film has good scratch resistance and low friction coefficient and can be applied in any photolithography such as a deep ultraviolet (DUV) lithography, an extreme ultraviolet (EUV), an immersion lithography, and a multiple patterning lithography to improve the yield of the photolithography.

To achieve the aforementioned and other objectives, the present invention discloses an embodiment of the protective film with high hardness and low friction coefficient deposited on a substrate 10, and the protective film comprises:

a buffer layer, on the substrate 10, and made of a metal such as chromium (Cr), titanium (Ti), aluminum (Al), copper (Cu), nickel (Ni), and cobalt (Co) or an alloy of any of the metals of the above in any proportion;

a passivation layer, on the buffer layer; wherein the passivation layer has at least one layer, selected from any of metal oxide (MxOy), metal nitride (MxNy), metal carbide (MxCy) and diamond-like carbon (DLC), and M is a metal element selected from any of nickel (Ni), copper (Cu), rhenium (Re), tungsten (W), cobalt (Co), iron (Fe), molybdenum (Mo), tin (Sn), aluminum (Al), zirconium (Zr) or a combination of any two or more of the above metals;

an interface layer, between the substrate and the buffer layer and made of MxNy, wherein M is a metal element selected from any of nickel (Ni), copper (Cu), rhenium (Re), tungsten (W), cobalt (Co), iron (Fe), molybdenum (Mo), tin (Sn), or a combination of any two or more of the above metals, wherein N is a non-metal element selected from any of phosphorus (P) or boron (B); x and y are atomic percentages; x is in between 80 at % to 95 at %; and y is in between 5 at % to 20 at %.

In the protective film with high hardness and low friction coefficient in accordance with this embodiment of the present invention, the substrate is a surface of the mask package box used in any of the following processes: a deep ultraviolet (DUV) lithography, an extreme ultraviolet (EUV), an immersion lithography, or a multiple patterning lithography.

In the protective film with high hardness and low friction coefficient in accordance with this embodiment of the present invention, the substrate is selected from any one or combination of metal materials such as aluminum, aluminum alloy, stainless steel, etc.; or non-metal material such as glass, quartz, polymer, etc.

In the protective film with high hardness and low friction coefficient in accordance with this embodiment of the present invention, the passivation layer has at least one layer.

In the protective film with high hardness and low friction coefficient in accordance with this embodiment of the present invention, the thickness of the passivation layer is in between 500 nm to 3 um.

In the protective film with high hardness and low friction coefficient in accordance with this embodiment of the present invention, the passivation layer has a hardness (H1) at least greater than 560 HV.

In the protective film with high hardness and low friction coefficient in accordance with this embodiment of the present invention, the passivation layer comprises a plurality of sublayers and the hardness of the plurality of sublayers decreases from top to bottom. In other words, the hardness of the upper sublayer is greater than the hardness of the lower sublayer in the passivation layer.

### BRIEF DESCRIPTION OF THE DRAWINGS

FIG. 1 is an exploded view of a conventional mask package box; and

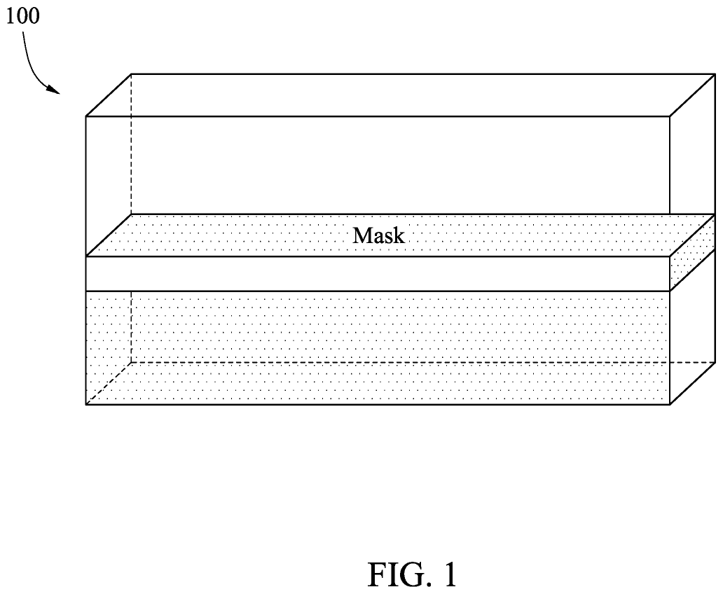

FIG. 2 is a cross-sectional side view of a protective film with high hardness and low friction coefficient of the present invention.

### DESCRIPTION OF THE PREFERRED EMBODIMENTS

The objectives, technical characteristics and effects of the present invention will become apparent with the detailed description of preferred embodiments accompanied with the illustration of related drawings. It is intended that the embodiments and drawings disclosed herein are to be considered illustrative rather than restrictive.

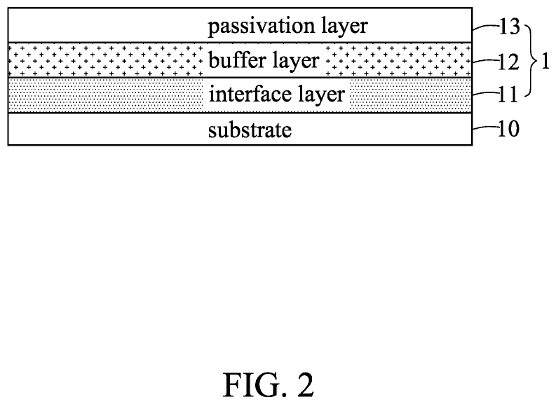

With reference to FIG. 2 for a cross-sectional side view of a protective film 1 with high hardness and low friction coefficient in accordance with the present invention, the protective film 1 is coated onto a substrate 10, wherein the substrate 10 is a surface of a mask package box. It is easy to understand that after the protective film with high hardness and low friction coefficient 1 of the present invention is coated onto the mask package box, the performance of the photolithographic process equipment with the protective film of the present invention can be improved significantly. The mask package box coated with the protective film is generally made of aluminum, aluminum alloy, or stainless steel.

In FIG. 2, the protective film with high hardness and low friction coefficient 1 of the present invention comprises an interface layer 11 formed on the substrate 10, at least one buffer layer (for adhesion) 12 is formed on the interface layer 11; a passivation layer 13, is formed on the buffer layer 12 by a single-layer or a multiple-layer coating method; the buffer layer 12 is primarily used for improving the adhesion between the passivation layer 13 and the interface layer 11. It is noteworthy that although FIG. 2 shows the interface layer 11, yet the interface layer 11 can be omitted in other embodiment without affecting the effect and spirit of the present invention. In general, the material of the interface layer 11 is selected from nickel (Ni), copper (Cu), rhenium (Re), tungsten (W), cobalt (Co), iron (Fe), molybdenum (Mo), tin (Sn), or a combination of any two or more of the above metals; the material of the buffer layer 12 is selected from chromium (Cr), titanium (Ti), aluminum (Al), copper (Cu), nickel (Ni), cobalt (Co), or any alloy of the above metals, and the buffer layer 12 has a thickness in between 10 nm to 100 nm. In FIG. 2, the passivation layer 13 is formed on the interface layer 12, the material of the passivation layer 13 is selected from any or a combination of metal oxides including but not limited to alumina (Al₂O₃), zirconium dioxide (ZrO₂), diamond-like carbon (DLC) membrane, titanium nitride (TiN), chromium nitride (CrN), titanium aluminum nitride (TiAlN), tungsten carbide (WC), metal nitride, or metal carbide. The passivation layer 13 can be a single layer structure as well as a multi layer structure. Based on the design of the present invention, the total number of layers of the passivation layer 13 can be combined as one layer (as shown in FIG. 2). In this invention, the passivation layer 13 can be deposited by an electronic gun evaporation by, spluttering, thermal evaporation, cathodic arc deposition, chemical vapor deposition, electrochemical deposition, spin coating, sol-gel process and hydrothermal coating. In addition, other subsequent processes including but not limited to annealing, oxygen plasma oxidation, etc., are noteworthy that any preparation method not mentioned but having the same or equivalent effects are also included in the scope of the present invention.

To further reduce the friction coefficient of the passivation layer 13, the surface of the passivation layer 13 is polished, such that the surface roughness is smaller than 500 nm. In a preferred embodiment, the surface roughness is smaller than 100 nm, and the surface polishing method is selected from mechanical abrasive polishing, electrolytic polishing, plasma polishing, etc., such that the friction coefficient is smaller than 0.07.

In an embodiment of the present invention, the passivation layer has a thickness in between 500 nm to 3 μm and capable of withstanding a pressure of 6 Gpa, a surface roughness below 100 nm, and a hardness of at least 600 HV.

Based on the design of the present invention, the interface layer 11 is made of MxNy, wherein M is a metal element selected from nickel (Ni), copper (Cu), rhenium (Re), tungsten (W), cobalt (Co), iron (Fe), molybdenum (Mo), tin (Sn), or a combination of any two or more of the above metals, and N is a non-metal element selected from phosphorus (P) or boron (B). For example, the interface layer 11 is made of a material such as Ni—P, Ni—B, Ni—Cu—P, Ni—Re—P, Ni—W—P, Co—P, Co—B, Fe—Sn—B, Fe—W—B, Fe—Mo—B, Fe—Mo—W—B, or Ni—Sn—Cu—P. It is noteworthy that x and y are atomic percentage, and x is in between 80 at % to 95 at %, and y is in between 5 at % to 20 at %.

To further improve and adjust the mechanical property of the protective film with high hardness and low friction coefficient 1 of the present invention, the interface layer 11 further comprises at least one element selected from antimony (Sb), zinc(Sn), cadmium (Cd), or iron (Fe). It is noteworthy that the atomic percentage of the above elements is less than 4%.

Based on the design of the present invention, the protective film with high hardness and low friction coefficient at least can withstand a force of 0.4 N applied by a diamond probe (having a radius of 0.25 mm) at room temperature.

While the invention has been described by means of specific embodiments, numerous modifications and variations could be made thereto by those skilled in the art without departing from the scope and spirit of the invention as set forth in the claims.

What is claimed is:

1. A protective film with high hardness and low friction coefficient, deposited on a substrate, comprising:
a buffer layer, on the substrate; and
a dielectric passivation layer, on the buffer layer.

2. The protective film with high hardness and low friction coefficient in accordance with claim 1, further comprising an interface layer between the substrate and the buffer layer.

3. The protective film with high hardness and low friction coefficient in accordance with claim 1, wherein the passivation layer has at least one layer.

4. The protective film with high hardness and low friction coefficient in accordance with claim 1, wherein the passivation layer has a thickness in between 500 nm to μm.

5. The protective film with high hardness and low friction coefficient in accordance with claim 1, wherein the Vickers hardness (H1) of the passivation layer is greater than 560 HV

6. The protective film with high hardness and low friction coefficient in accordance with claim 1, wherein the friction coefficient of the passivation layer is smaller than 0.07.

7. The protective film with high hardness and low friction coefficient according to claim 1, wherein the passivation layer comprises a plurality of sublayers, and the hardness of the upper sublayer is greater than the hardness of the lower sublayer.

8. The protective film with high hardness and low friction coefficient in accordance with claim 1, wherein the thickness of the passivation layer is in between 500 nm to 3 μm, and can withstand a pressure of 6 Gpa with a surface roughness below 100 nm, and at least 600 HV hardness.

9. The protective film with high hardness and low friction coefficient in accordance with claim 7, wherein the thickness of the buffer layer is in between 10 nm to 100 nm.

10. The protective film with high hardness and low friction coefficient in accordance with claim 7, wherein the surface roughness (Ra) of the protective film is at least smaller than 500 nm.

11. The protective film with high hardness and low friction coefficient in accordance with claim 1, wherein the protective film can withstand a force of 0.4 N applied by a diamond probe (having a radius of 0.25 mm).
